(19) United States
(12) Patent Application Publication
(10) Pub. No.: US 2024/0327093 A1
(43) Pub. Date: Oct. 3, 2024

(54) ENCLOSURE WITH IMPACT REDUCING FINS CONFIGURED TO PROTECT A SECOND ENCLOSURE INSIDE THE ENCLOSURE

(71) Applicant: PPC BROADBAND, INC., East Syracuse, NY (US)

(72) Inventors: Henry SAUVAIN, Syracuse, NY (US); Noah MONTENA, Syracuse, NY (US)

(73) Assignee: PPC BROADBAND, INC., East Syracuse, NY (US)

(21) Appl. No.: 18/621,947

(22) Filed: Mar. 29, 2024

Related U.S. Application Data
(60) Provisional application No. 63/456,107, filed on Mar. 31, 2023.

(51) Int. Cl. B65D 81/02

(52) U.S. Cl. CPC B65D 81/02

(57) ABSTRACT

A container system for protecting a component from impact includes a container configured to contain a second container therein with a cover of the second container being adjacent to a cover of the container. An impact reducing portion is configured to extend from an outer surface of the cover of the container in a direction away from the cover of the second container; the impact reducing portion is configured to deform in response to an impact force on the impact reducing portion that is less than a minimum impact force in response to which the cover is configured to deform; and the impact reducing portion is structurally configured to prevent an impact force on the impact reducing portion that is less than the minimum impact force from being transferred to the second container so as to protect the second container and an electronic component container in the second container.

### CROSS-REFERENCE TO RELATED APPLICATION

This application claims the benefit of U.S. Provisional Application No. 63/456,107, filed Mar. 31, 2023, pending, the disclosure of which is hereby incorporated by reference herein in its entirety.

### BACKGROUND

The present invention relates generally to enclosures. More particularly, the present invention relates an outer enclosure that reduces the effect of an impact on in inner enclosure.

Conventional systems can include foam spacers or springs to provide suspension of an inner container in an outer container to absorb impact. These systems can allow undesirable movement of the inner container in the outer container and/or do not sufficiently protect the inner container from impacts to which the outer container is subjected.

There is a need for a system that provides secure location of an inner container in an outer container while also protecting the inner container from impacts imparted onto the outer container.

### SUMMARY

The present disclosure provides a much needed system for protecting a component inside an inner container, where the inner container is located inside an outer container.

Embodiments provide a first impact reducing portion on a first container that is structurally configured to prevent an impact force on the first impact reducing portion that is less than a first minimum impact force from being transferred to a second impact reducing portion on a second container so as to protect the second container contained in the first container; and the second impact reducing portion is structurally configured to prevent an impact force on the second impact reducing portion that is less than a second minimum impact force from being transferred to an electronic component contained in the second container so as to protect the electronic component container in the second container

Embodiments provide a system wherein an outer impact structure is configured to deform in response to an impact acting on an outer container so as to absorb the impact such that an inner container is subjected to a force less than the impact so as to protect a component in the inner container.

Embodiments provide a protective container system for protecting a component from impact that includes: an outer container comprising an outer base and an outer cover; and an inner container comprising an inner base and an inner cover. The outer cover and the outer base define an outer volume; the inner cover and the inner base define an inner volume; the inner volume is configured to contain a component to be protected; the outer volume is configured to contain the inner container; the outer base comprises lower locating structure that is configured to limit movement of the inner container relative to the outer container; the outer cover comprises upper locating structure that is configured to limit movement of the inner container relative to the outer container; the upper locating structure and the lower locating structure are configured to prevent movement of the inner container relative to the outer container when the outer cover is in a closed position on the outer base; the inner container comprises inner impact structure that is configured to contact at least a portion of the upper locating structure when the outer cover is in the closed position; the inner impact structure of the inner container extends from the inner cover in the direction of the outer cover; the inner impact structure of the inner container is configured to deform in response to a first predetermined force; the inner cover is configured to not deform in response to the first predetermined force; the inner impact structure of the inner container comprises a fin or a pin; the outer cover comprises outer impact structure that extends outwardly from the outer cover; the outer impact structure has a distal end opposite to the outer cover, the distal end has a surface, and the surface of the distal end is sloped such that the distal end is at a different distance from the outer cover at different positions along the distal end; the outer impact structure of the outer cover is configured to deform in response to a second predetermined force; the outer cover is configured to not deform in response to the second predetermined force; the outer impact structure of the outer cover comprises a fin or a pin; and the outer impact structure is configured to deform in response to an impact acting on the outer container so as to absorb the impact such that the inner container is subjected to a force less than the impact so as to protect a component in the inner container.

Embodiments provide a protective container system for protecting a component from impact, including: a first container comprising a first base portion and a first cover portion; and a second container comprising a second base portion and a second cover portion. The first container may be configured to contain the second container therein with the second cover portion being adjacent to the first cover portion; the second container may be configured to contain an electronic component therein with the electronic component being adjacent to the second cover portion; the first container may include a receiving portion that may be structurally configured to prevent movement of the second container relative to the first container when the first cover portion is in a closed position relative to the first base portion; the first container may comprise a first impact reducing portion that may be configured to extend from an outer surface portion of the first cover portion in a direction away from the second cover portion; the second container may comprise a second impact reducing portion that may be configured to extend from the second cover portion in a direction toward the first cover portion; the first impact reducing portion may be structurally configured to deform in response to a first impact force on the first impact reducing portion that is less than a first minimum impact force in response to which the first cover portion is configured to deform; the second impact reducing portion may be structurally configured to deform in response to a second impact force on the second impact reducing portion that is less than a second minimum impact force in response to which the second cover portion is configured to deform; the first impact reducing portion may be structurally configured to prevent an impact force on the first impact reducing portion that is less than the first minimum impact force from being transferred to the second impact reducing portion so as to protect the second container contained in the first container; and the second impact reducing portion may be structurally configured to prevent an impact force on the second impact reducing portion that is less than the second minimum impact force from being transferred to an electronic component contained in the second container so as to protect the electronic component container in the second container.

In embodiments, the receiving portion may be configured as a structural support of the first cover portion.

In embodiments, the first impact reducing portion may comprise a fin.

In embodiments, the fin may be a first fin, and the first impacting reducing portion may further comprise a second fin.

In embodiments, the first fin and the second fin may be different sizes.

In embodiments, the first fin may be configured to extend a first distance from the outer surface portion of the first cover portion, the second fin may be configured to extend a second distance from the outer surface portion of the first cover portion, and the first distance and the second distance may be different.

In embodiments, the first impact reducing portion may comprise a first portion that may be configured to extend from the outer surface portion of the first cover portion a first extension distance, and first impact reducing portion may comprise a second portion that may be configured to extend from the outer surface portion of the first cover portion a second extension distance, and the first extension distance and the second extension distance may be different.

Embodiments provide a protective container system for protecting a component from impact, including: a first container comprising a first base portion and a first cover portion; and a second container comprising a second base portion and a second cover portion. The first container may be configured to contain the second container therein with the second cover portion being adjacent to the first cover portion; the second container may be configured to contain an electronic component therein with the electronic component being adjacent to the second cover portion; the first container may comprise a first impact reducing portion that may be configured to extend from an outer surface portion of the first cover portion in a direction away from the second cover portion; the first impact reducing portion may be structurally configured to deform in response to a first impact force on the first impact reducing portion that is less than a first minimum impact force in response to which the first cover portion is configured to deform; and the first impact reducing portion may be structurally configured to prevent an impact force on the first impact reducing portion that is less than the first minimum impact force from being transferred to the second container so as to protect the second container contained in the first container and an electronic component container in the second container.

In embodiments, the first container may include a receiving portion that may be structurally configured to prevent movement of the second container relative to the first container when the first cover portion is in a closed position relative to the first base portion.

In embodiments, the second container may comprise a second impact reducing portion that may be configured to extend from the second cover portion in a direction toward the first cover portion.

In embodiments, the second impact reducing portion may be structurally configured to deform in response to a second impact force on the second impact reducing portion that is less than a second minimum impact force in response to which the second cover portion is configured to deform.

In embodiments, the second impact reducing portion may be structurally configured to prevent an impact force on the second impact reducing portion that is less than the second minimum impact force from being transferred to an electronic component contained in the second container so as to protect the electronic component container in the second container.

In embodiments, the first impact reducing portion may comprise a first impact reducing portion first portion and a first impact reducing portion second portion.

In embodiments, the first impact reducing portion first portion and the first impact reducing portion second portion may be different sizes.

In embodiments, the first impact reducing portion first portion may be configured to extend a first distance from the outer surface portion of the first cover portion, the first impact reducing portion second portion may be configured to extend a second distance from the outer surface portion of the first cover portion, and the first distance and the second distance may be different.

In embodiments, the first impact reducing portion first portion may not directly contact the first impact reducing portion second portion.

Embodiments provide a protective container system for protecting a component from impact, including: a container comprising a base portion and a cover portion. The container may be configured to contain a second container therein with a cover portion of the second container being adjacent to the cover portion of the container; the container may comprise an impact reducing portion that may be configured to extend from an outer surface portion of the cover portion of the container in a direction away from the cover portion of the second container; the impact reducing portion may be structurally configured to deform in response to an impact force on the impact reducing portion that is less than a minimum impact force in response to which the cover portion is configured to deform; and the impact reducing portion may be structurally configured to prevent an impact force on the impact reducing portion that is less than the minimum impact force from being transferred to the second container so as to protect the second container contained in the first container and an electronic component container in the second container.

Embodiments may further comprise a second container that may comprise a second base portion and a second cover portion.

In embodiments, the second container may be configured to contain an electronic component therein with the electronic component being adjacent to the second cover portion.

In embodiments, the first container may include a receiving portion that may be structurally configured to prevent movement of the second container relative to the first container when the first cover portion is in a closed position relative to the first base portion.

In embodiments, the second container may comprise a second impact reducing portion that may be configured to extend from the second cover portion in a direction toward the first cover portion.

In embodiments, the second impact reducing portion may be structurally configured to deform in response to a second impact force on the second impact reducing portion that is less than a second minimum impact force in response to which the second cover portion is configured to deform.

In embodiments, the second impact reducing portion may be structurally configured to prevent an impact force on the second impact reducing portion that is less than the second minimum impact force from being transferred to an electronic component contained in the second container so as to protect the electronic component container in the second container.

In embodiments, the impact reducing portion may comprise an impact reducing portion first portion and an impact reducing portion second portion.

In embodiments, the impact reducing portion first portion and the impact reducing portion second portion may be different sizes.

In embodiments, the impact reducing portion first portion may be configured to extend a first distance from the outer surface portion of the cover portion, the impact reducing portion second portion may be configured to extend a second distance from the outer surface portion of the cover portion, and the first distance and the second distance may be different.

In embodiments, the impact reducing portion first portion may not directly contact the impact reducing portion second portion.

Various aspects of the system, as well as other embodiments, objects, features and advantages of this disclosure, will be apparent from the following detailed description of illustrative embodiments thereof, which is to be read in conjunction with the accompanying drawings.

### BRIEF DESCRIPTION OF THE DRAWINGS

FIG. 1 is a front perspective view of an enclosure in accordance with various aspects of the disclosure.

FIG. 2 is a top perspective view the enclosure of FIG. 1 in an open state.

FIG. 3 is a bottom perspective view of the enclosure of FIG. 1 in an open state.

FIG. 4 is a side view of the enclosure of FIG. 1 in an open state.

FIG. 5 is a side view of the enclosure of FIG. 1 in a closed state.

FIG. 6 is a perspective view on an inner enclosure.

FIG. 7 is a side sectional view of the enclosure of FIG. 1 in a closed state and showing the inner enclosure of FIG. 6.

FIG. 8 is a front sectional view of the enclosure of FIG. 1 in a closed state and showing the inner enclosure of FIG. 6.

FIG. 9 is a perspective view of an alternate embodiment of the enclosure of FIG. 1.

FIG. 10 is a perspective view of an alternate embodiment of the enclosure of FIG. 1.

FIG. 11 is a top plan view of the enclosure of FIG. 10.

FIG. 12 is a perspective view of an alternate embodiment of the enclosure of FIG. 1.

FIG. 13 is a top plan view of the enclosure of FIG. 12.

FIG. 14 is a perspective view of an alternate embodiment of a cover of the enclosure of FIG. 1.

FIG. 15 is a top plan view of the cover of FIG. 14.

FIG. 16 is a perspective view of an alternate embodiment of a cover of the enclosure of FIG. 1.

FIG. 17 is a top plan view of the cover of FIG. 16.

FIG. 18 is a top plan view of an alternate embodiment of a cover of the enclosure of FIG. 1.

FIG. 19 is a partial perspective view of an alternate embodiment of a cover of the enclosure of FIG. 1.

FIG. 20 is a front view of the cover of FIG. 19.

FIG. 21 is a partial perspective view of an alternate embodiment of a cover of the enclosure of FIG. 1.

### DETAILED DESCRIPTION OF EMBODIMENTS

Embodiments of the disclosure provide a system wherein an outer impact structure is configured to deform in response to an impact acting on an outer container so as to absorb the impact such that an inner container is subjected to a force less than the impact so as to protect a component in the inner container.

Embodiments provide a first impact reducing portion on a first container that is structurally configured to prevent an impact force on the first impact reducing portion that is less than a first minimum impact force from being transferred to a second impact reducing portion on a second container so as to protect the second container contained in the first container; and the second impact reducing portion is structurally configured to prevent an impact force on the second impact reducing portion that is less than a second minimum impact force from being transferred to an electronic component contained in the second container so as to protect the electronic component container in the second container.

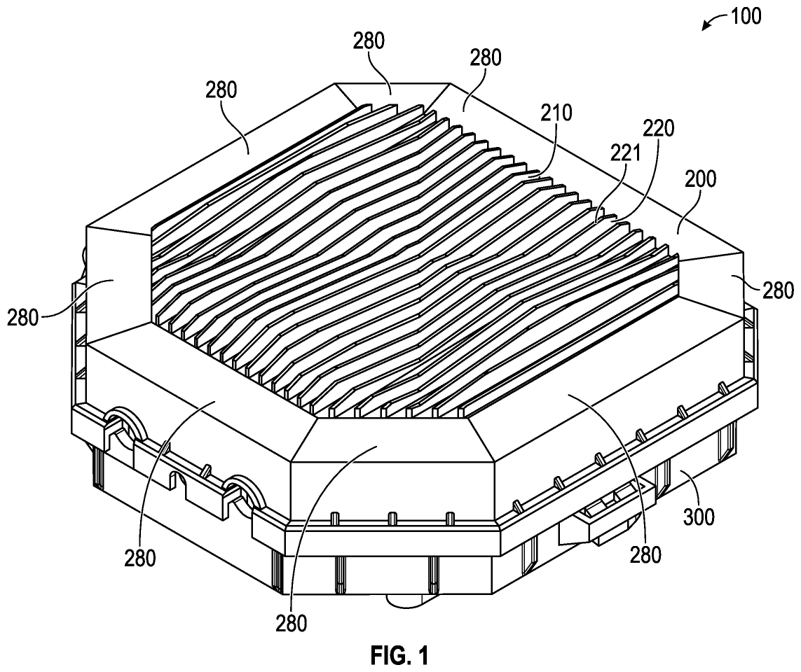

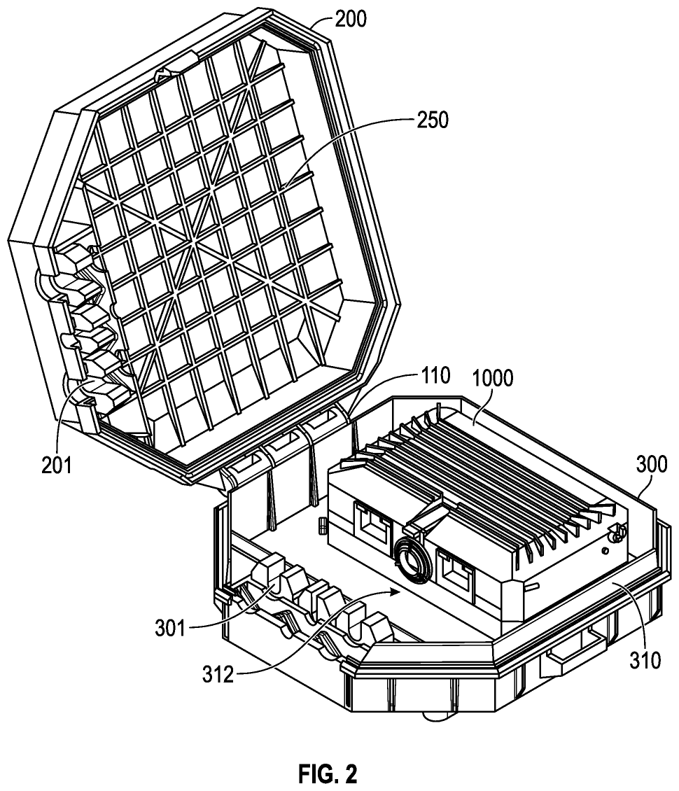

FIGS. 1 and 2 show an exemplary first container, for example, an outer enclosure, 100 in accordance with embodiments of the disclosure. In this example, the outer enclosure 100 has a first base portion, for example, an outer base, 300 and a first cover portion, for example, an outer cover, 200. The outer cover 200 is attached to the outer base 300 by a hinge 110. The outer cover 200 has, in this example, an impact reduction portion, for example, an outer impact structure, 210 that extends outwardly from an outer surface portion of the outer cover 200. The outer impact structure 210 is configured to absorb at least a portion of an impact by deforming in response to a force that is less than the force needed to deform, or deform more than a predetermined amount, the outer cover 200. In this example, the outer impact structure 210 is a plurality of fins 220. In this example, each of the fins 220 has a distal end that has a surface 221. Surfaces 221 of the fins 220 extend along a curved or sloped path. This curved or sloped path deflects an object that impacts the outer cover 200 such that a portion of the force of the impact is deflected along the surface of the distal ends of the fins 220, thus reducing the impact imparted onto the outer cover 200. Reducing the impact imparted onto the outer cover 200 reduces the force transferred to a second container, for example, an inner enclosure, 1000 located inside the outer enclosure 100. Also shown in FIG. 1 are a plurality of sloped surfaces 280 on an upper area of the outer cover 200. The sloped surfaces 280 are configured to deflect an object that impacts the outer cover 200 and thereby reduce the force transmitted to the outer cover 200. The fins 220 and/or other structures of the outer impact structure 210 can be formed, for example, of a semi-rigid material such as polycarbonate or ABS. In embodiments, the fins 220 and/or other structures of the outer impact structure 210 are the same material as the outer cover 200. In other embodiments, the fins 220 and/or other structures of the outer impact structure 210 and the outer cover 200 are different materials.

FIG. 2 shows the outer cover 200 having bracing or other structure 250 on its inside surface. In embodiments, structure 250 provides structural support for the outer cover 200 to strengthen the outer cover 200 against deformation resulting from an impact. The structure 250 can also function as a receiving portion, for example, an upper locating structure that restricts the movement of the inner enclosure 1000 (as described in more detail, below). FIG. 2 shows the outer base 300 having perimeter walls 310 that define a volume 312 that is configured to contain the inner enclosure 1000. Also shown in FIG. 2 are cable port portions 201 on the outer cover 200 and cable port portions 301 on the outer base 300. The cable ports provide, in this example, water-proof entry points for cables or other wires that are connected to the inner enclosure 1000 and/or a component or components housed in the inner enclosure 1000. Other embodiments have different forms and/or a different number of cable ports.

FIG. 3 shows an underside of the outer base 300 having a plurality of (in this example, four) mounts or feet 320 that are configured to facilitate mounting the outer enclosure 100 to a wall or other surface. FIG. 3 shows clearly the curved and/or sloped shape of the outer impact structure 210 (in this example, the surfaces 221 of the fins 220).

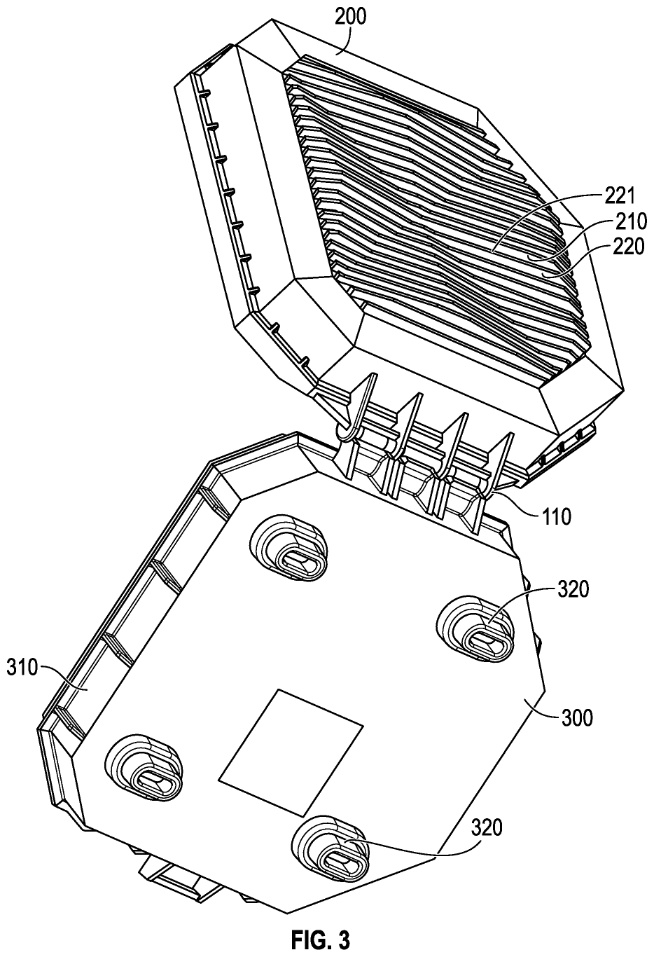

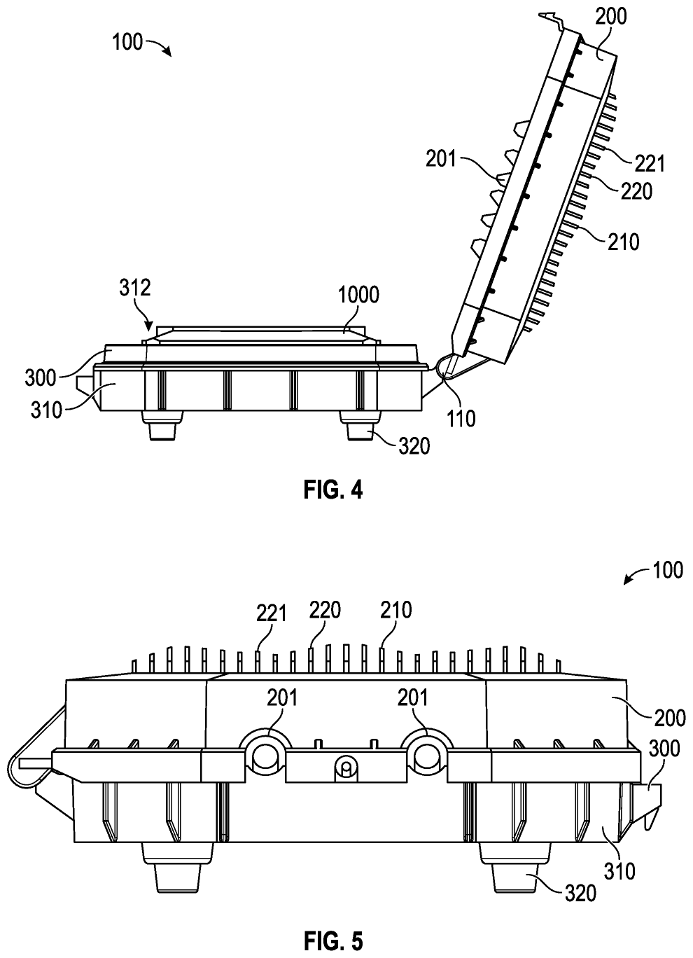

FIG. 4 is a side view of the outer enclosure 100 with the outer cover 200 in an open position. In this position, the inner enclosure 1000 can be seen located in the volume 312. FIG. 5 is a side view of the outer enclosure 100 with the outer cover 200 in a closed position with inner enclosure 1000 inside the outer enclosure 100. The different heights of the fins 220 are clearly shown in FIGS. 4 and 5.

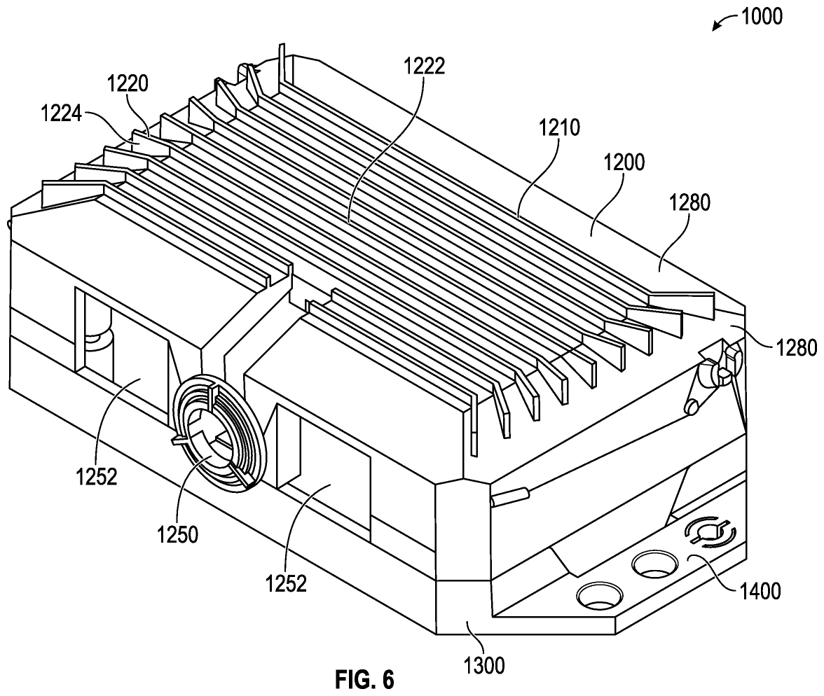

FIG. 6 shows the inner enclosure 1000 in the closed position. The inner enclosure 1000 is configured to house an electronic or other component that requires protection from the environment and/or potential impacts. In this example, the inner enclosure 1000 has a second base portion, for example, an inner base, 1300 and a second cover portion, for example, an inner cover, 1200 that is removably attached to the inner base 1300. The inner cover 1200 can be moved (for example, pivoted or completely removed) away from the inner base 1300 to provide access to an interior volume of the inner enclosure 1000. In this example, the inner enclosure 1000 has a plurality of (in this example, three) ports 1250, 1252 that provide connection points and/or passageways for cables and/or wires that are connected to the component inside the inner enclosure 1000. The inner enclosure 1000 is provided with mounting structure 1400 for mounting the inner enclosure 1000 to the outer base 300 inside volume 312.

FIG. 6 shows an example of a second impact reducing portion, for example, an inner impact structure 1210 on an upper surface of the inner cover 1200. The inner impact structure 1210 includes, in this example, a plurality of fins (or pins, or other protrusions) 1220 that extend outwardly from the inner cover 1200. The fins 1220 have a surface 1222 at a distal end of the fins 1220. In this example, the fins 1220 have portions 1224 that extend onto one or more of a plurality of sloped surfaces 1280 that form part of the upper surface of the inner cover 1200. Similarly to the outer impact structure 210, the inner impact structure 1210 is configured to absorb a portion of an impact by deforming in response to a force that is less than the force needed to deform the inner cover 1200.

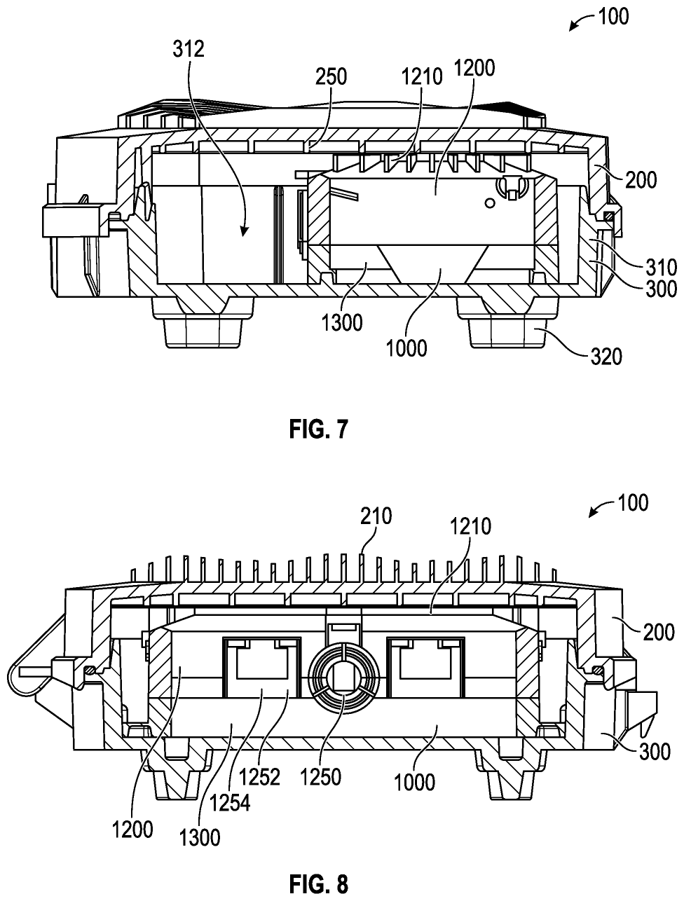

FIGS. 7 and 8 are partial sectional views through the outer enclosure 100 that shows the inner enclosure 1000 inside the outer enclosure 100 with the outer cover 200 in the closed position. FIGS. 7 and 8 show the inner impact structure 1210 of the inner enclosure 1000 contacting the structure 250 of the outer enclosure 100. In embodiments, this contact restricts the movement of the inner enclosure 1000 inside the outer enclosure 100. In the example shown in FIG. 2, the mounting structure 1400 of the inner enclosure 1000 secures the inner enclosure 1000 to the outer enclosure 100 such that contact between the inner impact structure 1210 and the outer cover 200 is not needed to restrict movement of the inner enclosure 1000. In some embodiments, the inner impact structure 1210 does not contact the outer cover 200 when the outer cover 200 is in the closed position. In embodiments, when an impact to the outer cover 200 is severe, a portion of the outer cover 200 can be pushed inward into contact with the inner impact structure 1210. In this situation, the inner impact structure 1210 can deform to reduce the force transmitted directly into the inner cover 1200 and/or redirect that force. FIG. 8 shows a cable receptacle 1254 located in each of the ports 1252.

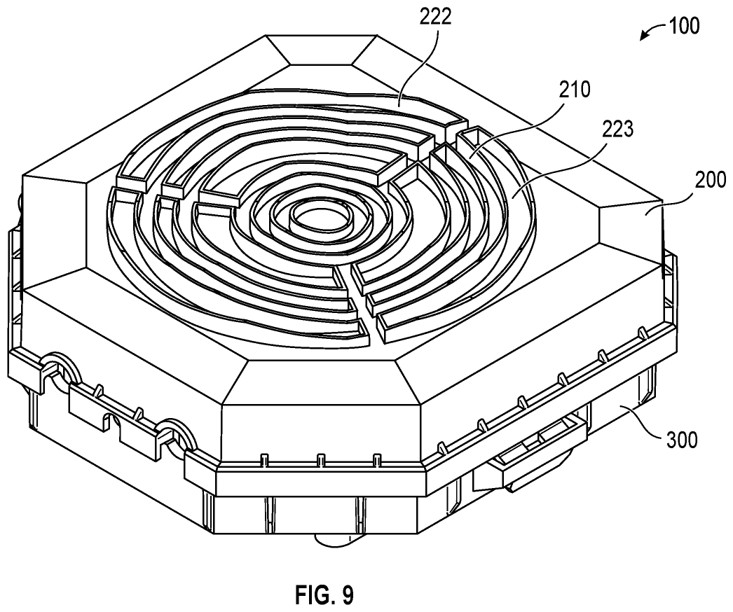

The outer impact structure can have many shapes including, but not limited to, patterns of rib-like features or pins (such as, for example fins 220). In embodiments, the fins/pins are proportionately thinner than walls of the outer cover 200. In embodiments, the fins have angled surfaces across the top in order to deflect some of the force of the impact. In embodiments, the fins/pins are configured to flex and absorb most of the force in the case of a smaller impact, redirecting the impacting object across an angled surface on the cover 200. In embodiments, the fins/pins are configured to break in the case of a larger impact, but would still absorb enough of the force from the impacting object required to protect the inner enclosure 1000 and the component in the inner enclosure 1000. FIGS. 9-21 shows various examples of patterns of fins that form the outer impact structure 210.

FIG. 9 shows an example of the outer cover 200 having a pattern of fins 222 that form a plurality of concentric circles and broken concentric circles 223. As shown in FIG. 9, the fins 222 have a curved and/or sloped upper surface caused by a varying height of the fins 222.

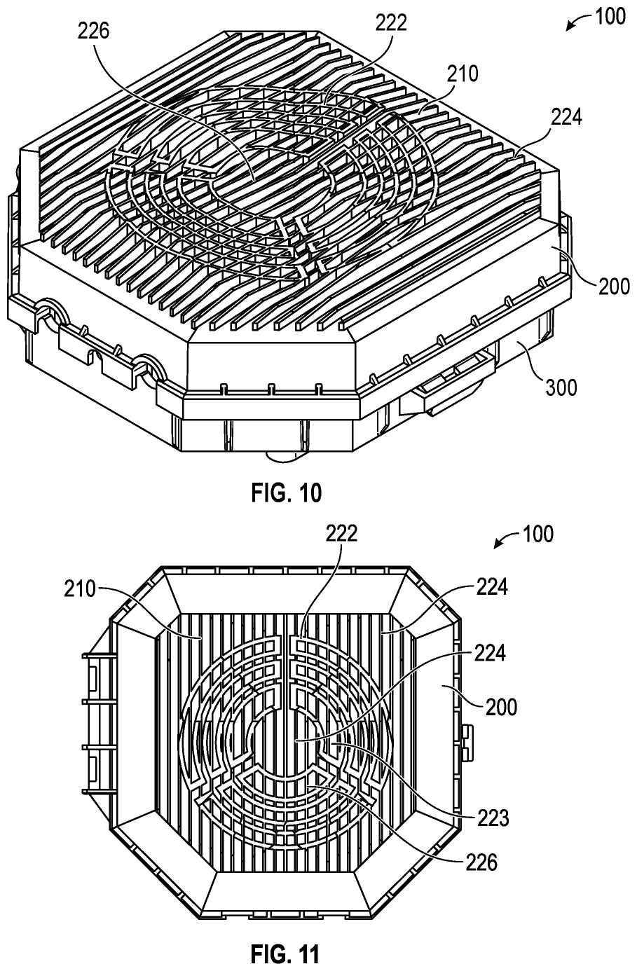

FIGS. 10 and 11 show an example of the outer cover 200 having a pattern of fins 222 in broken circles similar to that shown in FIG. 9, but with additional straight fins 226 (separated by spaces 223) inside the broken circles, and fins 224 outside of the broken circles. Fins 222, fins 224, and/or fins 226 can have curved, sloped, or straight upper surfaces.

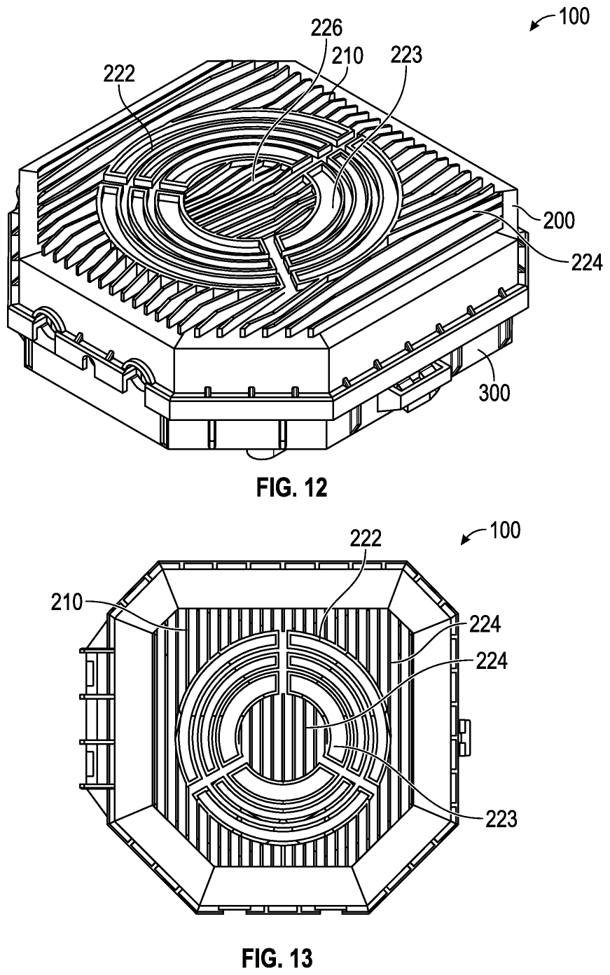

FIGS. 12 and 13 show an example of the outer cover 200 having the same pattern of fins 222 in broken circles as FIGS. 10 and 11, but with no fins inside the broken circles. This embodiment has the fins 224 outside of the broken circles. Fins 222 and/or fins 224 can have curved, sloped, or straight upper surfaces.

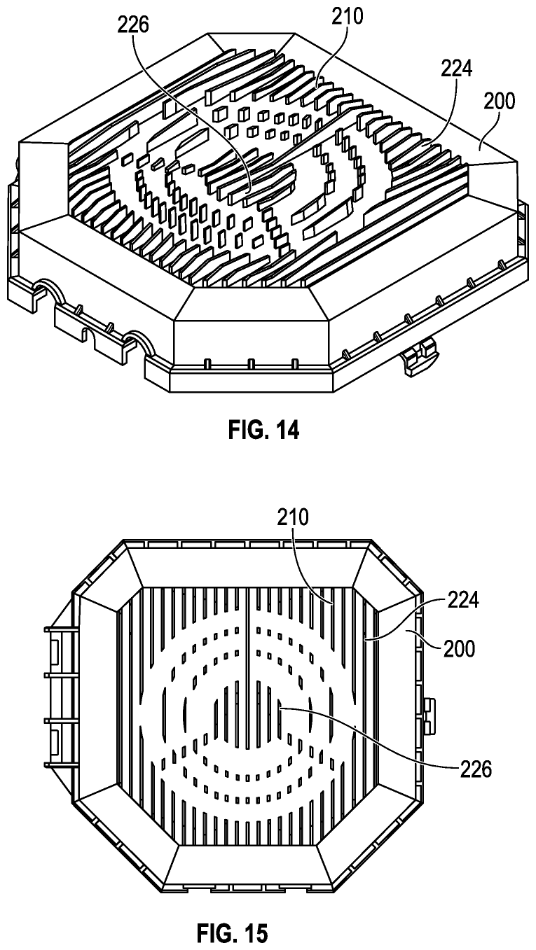

FIGS. 14 and 15 show an example of the outer cover 200 having the same pattern of broken circles as FIGS. 10 and 11, but with no fins 222 and no fins inside the areas of the broken circles. Fins 224 and/or fins 226 can have curved, sloped, or straight upper surfaces.

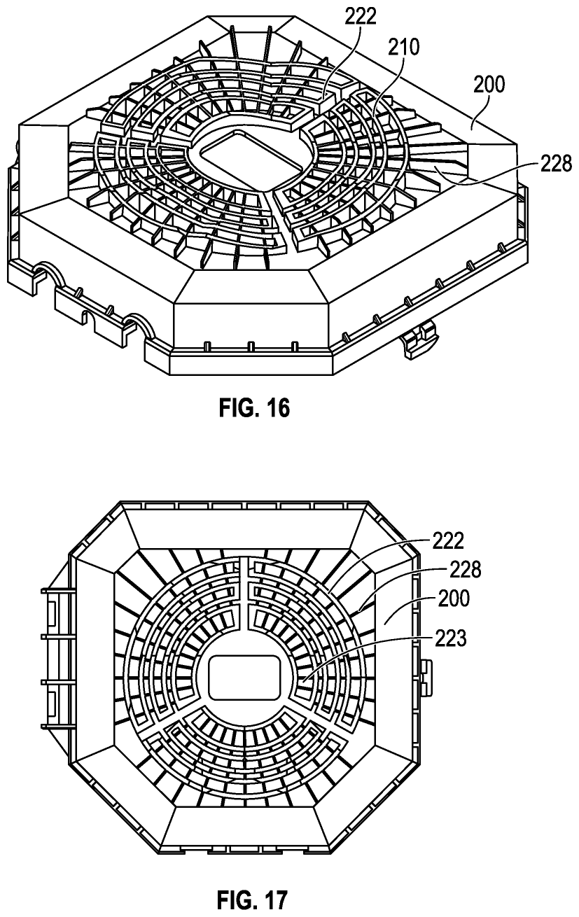

FIGS. 16 and 17 show an example of the cover 200 having a similar pattern of broken circles as FIGS. 10 and 11, but with radially positioned fins 228 instead of the parallel fins 224 of FIGS. 10 and 11. Fins 222 and/or fins 228 can have curved, sloped, or straight upper surfaces.

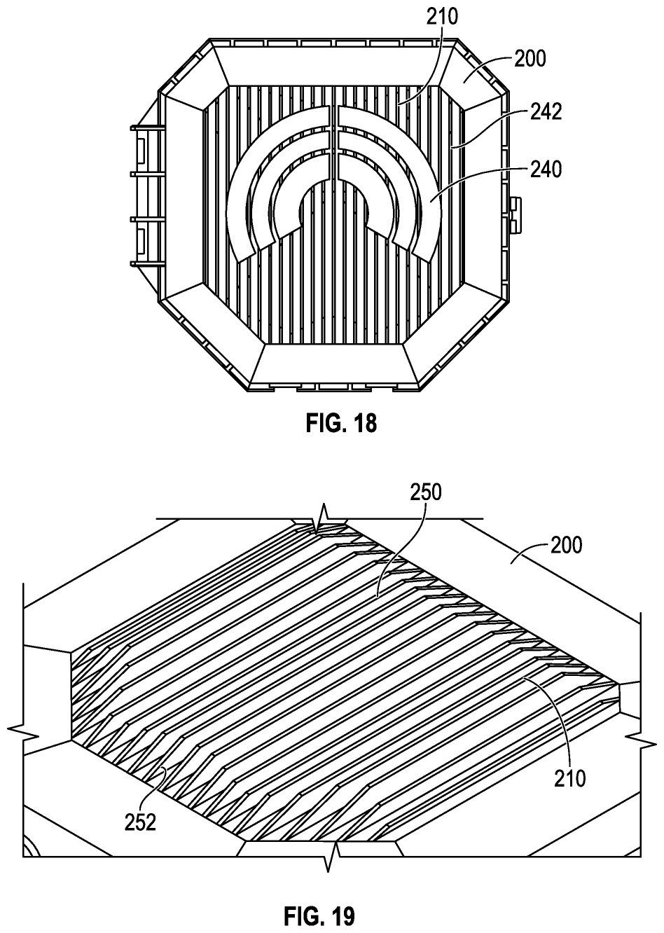

FIG. 18 shows an example of the cover 200 having a plurality of parallel fins 242, some of which are interrupted by a broken circle pattern of blank areas 240. Fins 242 can have curved, sloped, or straight upper surfaces.

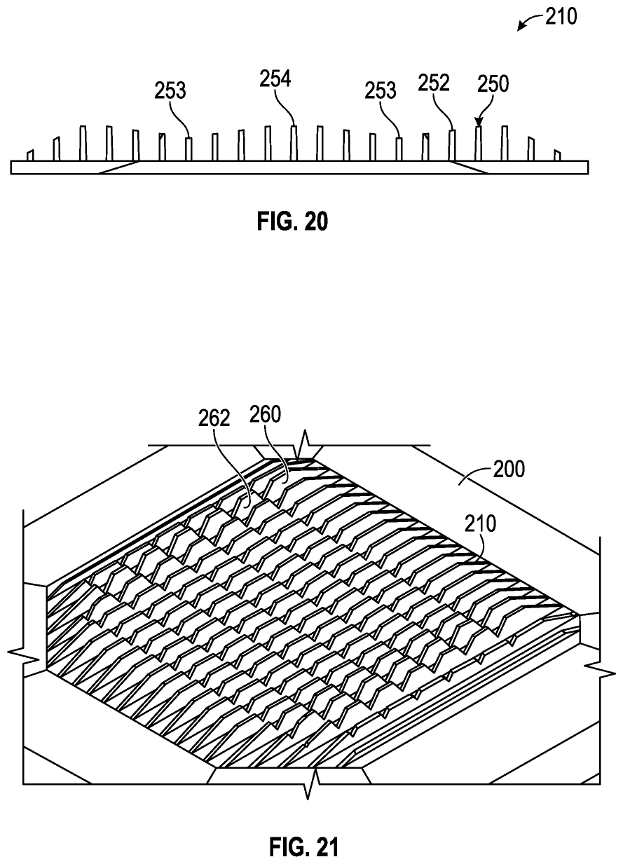

FIG. 19 shows an example of the cover 200 having parallel fins 250, 252 similar to the fins 242 of FIG. 18, except that they are not interrupted by the broken circle pattern of blank areas shown in FIG. 18. As shown in FIG. 20, the outer impact structure 210 includes fins 250, 252, 253, 254 of differing heights. For example, a first impact reducing portion first portion, or first fin, can have a different height than a first impact reducing portion second portion, or second fin. These different height fins help deflect an impacting object by effectively forming a sloped surface. The different height fins also result in different deformation due to them acting like levers of different length. Both of these features contribute to the dissipation of energy from an impacting object.

FIG. 21 shows an example of the outer cover 200 having a pattern of fins 260 that is similar to the pattern of fins shown in FIGS. 19 and 20, but with a plurality of notches or spaces in the fins 260 that result in a plurality of fin sections 262. These smaller fin sections 262 can bend or otherwise deform independently from one another which can allow deformation of the fin sections 262 with less force than that required to bend one of the fins 250. Also, if the impact is of sufficient strength to break a fin section 262, adjacent fin sections 262 may not be broken, which potentially provide against further impacts.

Although the illustrative embodiments of the present invention have been described herein with reference to the accompanying drawings, it is to be understood that the invention is not limited to those precise embodiments, and that various other changes and modifications may be effected therein by one skilled in the art without departing from the scope or spirit of the invention.

Various changes to the foregoing described and shown structures will now be evident to those skilled in the art. Accordingly, the particularly disclosed scope of the invention is set forth in the following claims.

What is claimed is:

1. A protective container system for protecting a component from impact, comprising:
a first container comprising a first base portion and a first cover portion;
a second container comprising a second base portion and a second cover portion;
wherein the first container is configured to contain the second container therein with the second cover portion being adjacent to the first cover portion;
wherein the second container is configured to contain an electronic component therein with the electronic component being adjacent to the second cover portion;
wherein the first container includes a receiving portion that is structurally configured to prevent movement of the second container relative to the first container when the first cover portion is in a closed position relative to the first base portion;
wherein the first container comprises a first impact reducing portion that is configured to extend from an outer surface portion of the first cover portion in a direction away from the second cover portion;
wherein the second container comprises a second impact reducing portion that is configured to extend from the second cover portion in a direction toward the first cover portion;
wherein the first impact reducing portion is structurally configured to deform in response to a first impact force on the first impact reducing portion that is less than a first minimum impact force in response to which the first cover portion is configured to deform;
wherein the second impact reducing portion is structurally configured to deform in response to a second impact force on the second impact reducing portion that is less than a second minimum impact force in response to which the second cover portion is configured to deform;
wherein the first impact reducing portion is structurally configured to prevent an impact force on the first impact reducing portion that is less than the first minimum impact force from being transferred to the second impact reducing portion so as to protect the second container contained in the first container; and
wherein the second impact reducing portion is structurally configured to prevent an impact force on the second impact reducing portion that is less than the second minimum impact force from being transferred to an electronic component contained in the second container so as to protect the electronic component container in the second container.

2. The protective container system of claim 1, wherein the receiving portion is configured as a structural support of the first cover portion.

3. The protective container system of claim 1, wherein the first impact reducing portion comprises a fin.

4. The protective container system of claim 3, wherein the fin is a first fin, and the first impacting reducing portion further comprises a second fin.

5. The protective container system of claim 4, wherein the first fin and the second fin are different sizes.

6. The protective container system of claim 5, wherein the first fin is configured to extend a first distance from the outer surface portion of the first cover portion, the second fin is configured to extend a second distance from the outer surface portion of the first cover portion, and the first distance and the second distance are different.

7. The protective container system of claim 1, wherein the first impact reducing portion comprises a first portion that is configured to extend from the outer surface portion of the first cover portion a first extension distance, and first impact reducing portion comprises a second portion that is configured to extend from the outer surface portion of the first cover portion a second extension distance, and the first extension distance and the second extension distance are different.

8. A protective container system for protecting a component from impact, comprising:
a first container comprising a first base portion and a first cover portion;
a second container comprising a second base portion and a second cover portion;
wherein the first container is configured to contain the second container therein with the second cover portion being adjacent to the first cover portion;
wherein the second container is configured to contain an electronic component therein with the electronic component being adjacent to the second cover portion;
wherein the first container comprises a first impact reducing portion that is configured to extend from an outer surface portion of the first cover portion in a direction away from the second cover portion;
wherein the first impact reducing portion is structurally configured to deform in response to a first impact force on the first impact reducing portion that is less than a first minimum impact force in response to which the first cover portion is configured to deform; and
wherein the first impact reducing portion is structurally configured to prevent an impact force on the first impact reducing portion that is less than the first minimum impact force from being transferred to the second container so as to protect the second container contained in the first container and an electronic component container in the second container.

9. The protective container system of claim 8, wherein the first container includes a receiving portion that is structurally configured to prevent movement of the second container relative to the first container when the first cover portion is in a closed position relative to the first base portion.

10. The protective container system of claim 8, wherein the second container comprises a second impact reducing portion that is configured to extend from the second cover portion in a direction toward the first cover portion.

11. The protective container system of claim 10, wherein the second impact reducing portion is structurally configured to deform in response to a second impact force on the second impact reducing portion that is less than a second minimum impact force in response to which the second cover portion is configured to deform.

12. The protective container system of claim 11, wherein the second impact reducing portion is structurally configured to prevent an impact force on the second impact reducing portion that is less than the second minimum impact force from being transferred to an electronic component contained in the second container so as to protect the electronic component container in the second container.

13. The protective container system of claim 8, wherein the first impact reducing portion comprises a first impact reducing portion first portion and a first impact reducing portion second portion.

14. The protective container system of claim 13, wherein the first impact reducing portion first portion and the first impact reducing portion second portion are different sizes.

15. The protective container system of claim 14, wherein the first impact reducing portion first portion is configured to extend a first distance from the outer surface portion of the first cover portion, the first impact reducing portion second portion is configured to extend a second distance from the outer surface portion of the first cover portion, and the first distance and the second distance are different.

16. The protective container system of claim 15, wherein the first impact reducing portion first portion does not directly contact the first impact reducing portion second portion.

17. A protective container system for protecting a component from impact, comprising:
a container comprising a base portion and a cover portion;
wherein the container is configured to contain a second container therein with a cover portion of the second container being adjacent to the cover portion of the container;
wherein the container comprises an impact reducing portion that is configured to extend from an outer surface portion of the cover portion of the container in a direction away from the cover portion of the second container;
wherein the impact reducing portion is structurally configured to deform in response to an impact force on the impact reducing portion that is less than a minimum impact force in response to which the cover portion is configured to deform; and
wherein the impact reducing portion is structurally configured to prevent an impact force on the impact reducing portion that is less than the minimum impact force from being transferred to the second container so as to protect the second container contained in the first container and an electronic component container in the second container.

18. The protective container system of claim 17, further comprising a second container comprising a second base portion and a second cover portion.

19. The protective container system of claim 18, wherein the second container is configured to contain an electronic component therein with the electronic component being adjacent to the second cover portion.

20. The protective container system of claim 19, wherein the first container includes a receiving portion that is structurally configured to prevent movement of the second container relative to the first container when the first cover portion is in a closed position relative to the first base portion.

21. The protective container system of claim 19, wherein the second container comprises a second impact reducing portion that is configured to extend from the second cover portion in a direction toward the first cover portion.

22. The protective container system of claim 21, wherein the second impact reducing portion is structurally configured to deform in response to a second impact force on the second impact reducing portion that is less than a second minimum impact force in response to which the second cover portion is configured to deform.

23. The protective container system of claim 22, wherein the second impact reducing portion is structurally configured to prevent an impact force on the second impact reducing portion that is less than the second minimum impact force from being transferred to an electronic component contained in the second container so as to protect the electronic component container in the second container.

24. The protective container system of claim 17, wherein the impact reducing portion comprises an impact reducing portion first portion and an impact reducing portion second portion.

25. The protective container system of claim 24, wherein the impact reducing portion first portion and the impact reducing portion second portion are different sizes.

26. The protective container system of claim 25, wherein the impact reducing portion first portion is configured to extend a first distance from the outer surface portion of the cover portion, the impact reducing portion second portion is configured to extend a second distance from the outer surface portion of the cover portion, and the first distance and the second distance are different.

27. The protective container system of claim 26, wherein the impact reducing portion first portion does not directly contact the impact reducing portion second portion.
